(19) United States
(12) Patent Application Publication
(10) Pub. No.: US 2005/0247945 A1
(43) Pub. Date: Nov. 10, 2005

(54) LED heat-radiating substrate and method for making the same

(75) Inventors: Chih-Sung Chang, Hsin Chu City (TW); Tzer-Perng Chen, Hsin Chu City (TW)

Correspondence Address: TROXELL LAW OFFICE PLLC, 5205 LEESBURG PIKE, SUITE 1404, FALLS CHURCH, VA, 22041, US

(73) Assignee: United Epitaxy Company, Ltd.

(21) Appl. No.: 10/841,639

(22) Filed: May 10, 2004

(51) Int. Cl. H01L 27/15

(52) U.S. Cl. 257/79

(57) ABSTRACT

An LED heat-radiating substrate and a method for making the same are proposed. The LED heat-radiating substrate has a low expansion layer body and two high thermal conductivity layer bodies formed at its two sides. Through mutual connection and containment of these layer bodies, the requirements of high heat-radiating effect and low expansion can be met. An LED structure can be arranged on the heat-radiating substrate to accomplish a high heat-radiating effect. Moreover, damage to the LED structure due to thermal expansion of the heat-radiating substrate can be avoided.

### FIELD OF THE INVENTION

The present invention relates to an LED heat-radiating substrate and a method for making the same and, more particularly, to a heat-radiating substrate applicable to an LED structure and a method for making the heat-radiating substrate.

### BACKGROUND OF THE INVENTION

For future applications in illumination and display, it is necessary to increase the current of light emitting diodes (LED) several or several hundred fold. The power consumption of LED thus increases several or several hundred fold. Of course, it is necessary to substantially change the conventional LED manufacturing method. In particular, the heat-radiating effect of LEDs ought to be effectively improved to enhance the light emission efficiency of LED.

Conventionally, an LED is formed by epitaxially growing a light-emitting structure on an appropriate substrate. For instance, an AlInGaP LED is formed on a GaAs substrate, while an AlInGaN LED is formed on a sapphire substrate. These substrates, however, have low thermal conductance. If the current is increased several fold, the generated heat can't be spread successfully, hence seriously affecting the light emission efficiency of the epitaxial semiconductor light emitting structure due to thermal effect. Moreover, the lifetime of the epitaxy semiconductor light emitting structure will decrease under high temperatures. Therefore, it is necessary to handle effectively the heat spread of LEDs used in high power applications.

In consideration of the above problem, a heat-radiating substrate was used in an LED. For instance, the conventional GaAs substrate is removed, and the semiconductor light emitting structure is adhered on a Si substrate. Because the Si substrate has a better thermal conductance than the GaAs substrate, the deterioration of light emission efficiency of LED can be mitigated. However, the Si substrate is still a semiconductor, whose thermal conductance will drop fast along with increase of temperature. Other semiconductor substrates also have this problem. Therefore, the heat radiation of LED is still a problem not effectively solved.

In nature, metals are material having the best thermal conductance. The thermal conductance of metals like gold, silver, copper and aluminum won't drop fast along with increase in temperature. These metals, however, can't be directly used as LED substrates because their thermal expansion coefficients are much larger than those of semiconductor materials. If an LED structure is directly adhered on a metal substrate, the lattice structure thereof will be destroyed during the manufacturing procedures of the LED structure like thermal melting and baking due to thermal expansion of the metal substrate, hence damaging the LED structure. How to find an appropriate heat-radiating substrate and a method for making -the same is thus an important issue to be dealt with urgently.

Accordingly, the present invention aims to solve the problems in the prior art.

### SUMMARY OF THE INVENTION

An object of the present invention is to provide an LED heat-radiating substrate with high thermal conductance and low expansion.

To achieve the above object, the present invention provides an LED heat-radiating substrate whereon an LED structure is disposed to radiate heat of the LED structure. The heat-radiating substrate comprises tiny structures of low expansion bodies and high thermal conductivity bodies, which are mutually connected and confined. An LED heat-radiating substrate with high thermal conductance and low expansion is thus formed.

To achieve the above object, the present invention also provides an LED heat-radiating substrate whereon an LED structure is disposed to radiate heat of the LED structure. The heat-radiating substrate comprises a low expansion layer body and two high thermal conductivity layer bodies. The high thermal conductivity layer bodies are fixedly disposed at upper and lower sides of the low expansion layer body. Heat of the LED structure is conducted via the high thermal conductivity layer bodies. Moreover, the expansion of the high thermal conductivity layer bodies is limited by the low expansion layer body.

To achieve the above object, the present invention also provides an LED heat-radiating substrate whereon an LED structure is disposed to radiate heat of the LED structure., The heat-radiating substrate comprises slabs composed of copper-tungsten alloy or copper-molybdenum alloy.

The present invention also provides a method for making an LED heat-radiating substrate. A low expansion layer body is formed. A high thermal conductivity layer bodies is then separately formed on upper and lower sides of the low expansion layer body to form a heat-radiating substrate with high thermal conductivity and low expansion.

The above low expansion layer body and high thermal conductivity layer bodies are mutually connected and confined.

The present invention also provides a method for making an LED heat-radiating substrate. High thermal conductivity powder bodies and low expansion powder bodies are provided. The high thermal conductivity powder bodies and the low expansion powder bodies are mixed. The mixed high thermal conductivity powder bodies and low expansion powder bodies are pressed to form a solid body The pressed solid body is then sintered to form a heat-radiating substrate with high thermal conductivity and low expansion. The present invention also provides a method for making an LED heat-radiating substrate. Low expansion powder bodies are provided. The low expansion powder bodies are pressed to form a solid body. The pressed solid body is sintered to form a sintered body having holes. The holes of the sintered body are permeated with a high thermal conductivity liquid. The high thermal conductivity liquid is then solidified in the sintered body to form a heat-radiating substrate with high thermal conductivity and low expansion.

### BRIEF DESCRIPTION OF THE DRAWINGS

The various objects and advantages of the present invention will be more readily understood from the following detailed description when read in conjunction with the appended drawing, in which:

FIG. 1 is an assembly diagram of an LED structure and a heat-radiating substrate of the present invention;

FIG. 2 is a diagram of a stratiform LED heat-radiating substrate of the present invention;

FIG. 3 is another diagram of a stratiform LED heat-radiating substrate of the present invention;

FIG. 4 is a diagram of a sintered LED heat-radiating substrate of the present invention;

FIG. 5 is another diagram of a sintered LED heat-radiating substrate of the present invention; and

FIG. 6 is a diagram of an LED heat-radiating substrate composed of alloys of the present invention.

### DETAILED DESCRIPTION OF THE PREFERRED EMBODIMENTS

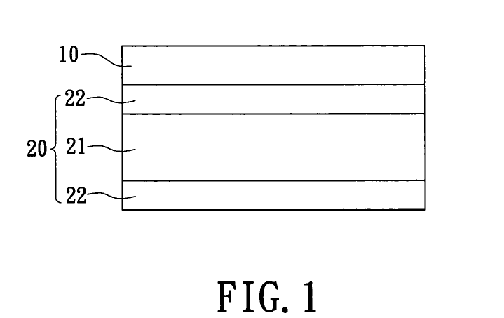

As shown in FIGS. 1 to 6, the present invention provides an LED heat-radiating substrate 20 whereon an LED structure 10 is disposed to radiate heat of the LED structure 10. The heat-radiating substrate 20 comprises low expansion bodies 21 and high thermal conductivity bodies 22, which are mutually connected and confined to form an LED heat-radiating substrate with high thermal conductance and low expansion.

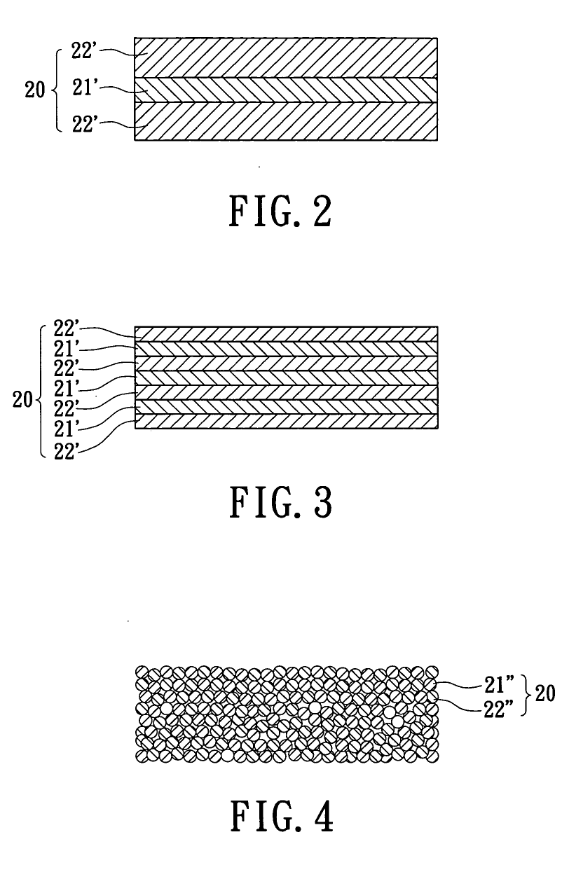

As shown in FIG. 2, the LED heat-radiating substrate 20 comprises a low expansion layer body 21′ and two high thermal conductivity layer bodies 22′.

The high thermal conductivity layer bodies 22′ are fixedly connected at upper and lower sides of the low expansion layer body 21′. When the LED structure 10 is arranged on one of the high thermal conductivity layer bodies 22, heat generated by the LED structure 10 will be conducted out. Moreover, expansion of the high thermal conductivity layer bodies 22′ is limited by the low expansion layer body 21′, thereby avoiding damage to the lattice of the LED structure 10 due to expansion of the high thermal conductivity layer bodies 22′. The low expansion layer body 21′ can be a tungsten (W) slab or a molybdenum (Mo) slab. The high thermal conductivity layer bodies 22′ can be sintered bodies disposed at upper and lower sides of the low expansion layer body 21′. These layer bodies are rolled and pressed together or welded together. The present invention also provides a method for making an LED heat-radiating substrate. A low expansion layer body 21′ is formed. High thermal conductivity layer bodies 22′ are then formed at upper and lower sides of the low expansion layer body 21′ to form a heat-radiating substrate with high thermal conductivity and low expansion.

The above low expansion layer body 21′ and high thermal conductivity layer bodies 22′ are mutually connected and confined.

The above layer bodies can be made by means of evaporation, electroplating, casting or electroforming. Reference is made to FIG. 3. The low expansion layer bodies 21′ can further be formed at outer sides of the high thermal conductivity layer bodies 22′, and the high thermal conductivity layer bodies 22′ can further be formed at outer sides of the low expansion layer bodies 21′, thereby forming a multi-layer heat-radiating substrate 20.

Reference is made to FIG. 4. The LED heat-radiating substrate 20 comprises tiny structures of the low expansion bodies 21 and the high thermal conductivity bodies 22, which are mutually connected and confined to form the LED heat-radiating substrate 20 with high thermal conductance and low expansion. The tiny structures of the low expansion bodies 21 are low expansion powder bodies 21″ such as tungsten (W) powder bodies, molybdenum (Mo) powder bodies, diamond powder bodies or silicon carbide (SiC) powder bodies. The tiny structures of the high thermal conductivity bodies 22 are high thermal conductivity powder bodies 22″ such as copper (Cu) powder bodies. The low expansion powder bodies 21″ and the high thermal conductivity powder bodies 22″ are sintered to form a sintered heat-radiating substrate 20.

The present invention also provides a method for making the sintered heat-radiating substrate 20. Thermal conductivity powder bodies 22″ and low expansion powder bodies 21″ are provided. The high thermal conductivity powder bodies 22″ and the low expansion powder bodies 21″ are mixed. The mixed high thermal conductivity powder bodies 22″ and low expansion powder bodies 21″ are pressed to form a solid body. The pressed solid body is then sintered to form a heat-radiating substrate with high thermal conductivity and low expansion.

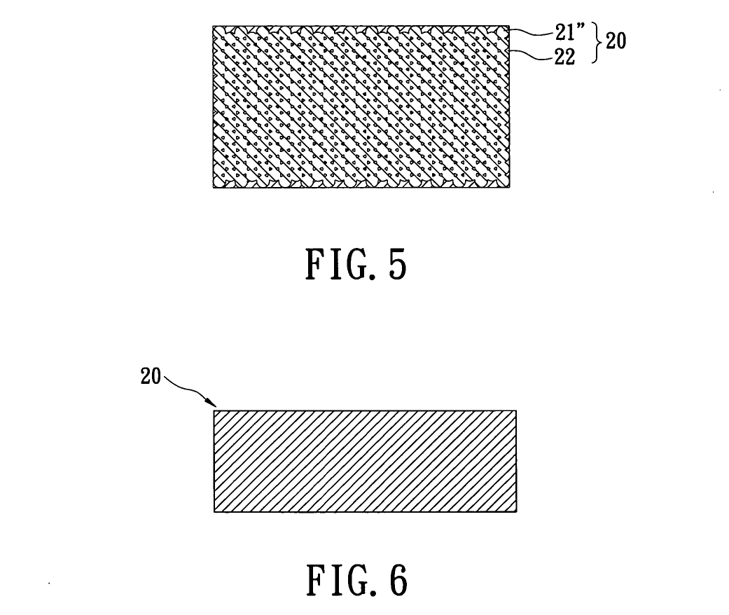

Reference is made to FIG. 5. The present invention also provides another method for making the heat-radiating substrate 20. The low expansion powder bodies 21″ is provided. The low expansion powder bodies 21″ are pressed to form a solid body. The pressed solid body is sintered to form a sintered body having holes. The holes of the sintered body are permeated with a high thermal conductivity liquid 22. The high thermal conductivity liquid 22 in the sintered body is then solidified to form a heat-radiating substrate with high thermal conductivity and low expansion.

The high thermal conductivity liquid 22 is liquid metal like liquid copper (Cu).

Reference is made to FIG. 6. The LED heat-radiating substrate 20 can be made of copper-tungsten (Cu—W) alloy or copper-molybdenum (Cu—Mo) alloy. Copper-tungsten (Cu—W) alloy powder bodies or copper-molybdenum (Cu—Mo) alloy powder bodies can be sintered to form a heat-radiating substrate 20 with high thermal conductance and low expansion.

To sum up, the present invention proposes an LED heat-radiating substrate to accomplish the effects of high thermal conductance and low expansion. When an LED structure is arranged on the heat-radiating substrate, it is not destroyed due to heat expansion and cold shrinkage of the heat-radiating substrate.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. An LED heat-radiating substrate whereon an LED structure is disposed to radiate heat of said LED structure, said LED heat-radiating substrate comprising tiny structures of low expansion bodies and high thermal conductivity bodies mutually connected and confined to accomplish high thermal conductivity and low expansion.

2. The LED heat-radiating substrate as claimed in claim 1, wherein the tiny structures of said low expansion bodies and said high thermal conductivity bodies are powder bodies mutually connected to form a sintered body.

3. The LED heat-radiating substrate as claimed in claim 1, wherein the tiny structures of said low expansion bodies are powder bodies mutually connected to form a sintered body having holes, and said high thermal conductivity bodies are accommodated in said holes of said sintered body.

4. The LED heat-radiating substrate as claimed in claim 1, wherein the tiny structures of said low expansion bodies are tungsten power bodies, molybdenum powder bodies, diamond powder bodies or silicon carbide powder bodies.

5. The LED heat-radiating substrate as claimed in claim 1, wherein the tiny structures of said high thermal conductivity bodies are copper bodies.

6. An LED heat-radiating substrate whereon an LED structure is disposed to radiate heat of said LED structure, said LED heat-radiating substrate comprising:
a low expansion body; and
high thermal conductivity bodies fixedly arranged on upper and lower sides of said low expansion body;
whereby said high thermal conductivity bodies are used to conduct heat of said LED structure, and said low expansion body is used to limit expansion of said high thermal conductivity bodies.

7. The LED heat-radiating substrate as claimed in claim 6, wherein said low expansion body is a tungsten layer body or a molybdenum layer body.

8. The LED heat-radiating substrate as claimed in claim 7, wherein said layer bodies are slabs.

9. The LED heat-radiating substrate as claimed in claim 6, wherein said high thermal conductivity bodies are copper layer bodies.

10. The LED heat-radiating substrate as claimed in claim 9, wherein said layer bodies are slabs.

11. The LED heat-radiating substrate as claimed in claim 6, wherein said high thermal conductivity layer bodies are powder-sintered bodies.

12. An LED heat-radiating substrate whereon an LED structure is disposed to radiate heat of said LED structure, said LED heat-radiating substrate comprising slabs composed of copper-tungsten alloy or copper-molybdenum alloy.

13. A method for making an LED heat-radiating substrate, the method comprising the steps of:
forming a low expansion layer body; and
separately forming high thermal conductivity layer bodies on upper and lower sides of said low expansion layer body to form a heat-radiating substrate with high thermal conductivity and low expansion, said low expansion layer body and said high thermal conductivity layer bodies being mutually connected and confined.

14. The method for making an LED heat-radiating substrate as claimed in claim 13, wherein said layer bodies are roller and pressed together.

15. The method for making an LED heat-radiating substrate as claimed in claim 13, wherein said layer bodies are welded together.

16. The method for making an LED heat-radiating substrate as claimed in claim 13, wherein said layer bodies are made by means of evaporation.

17. The method for making an LED heat-radiating substrate as claimed in claim 13, wherein said layer bodies are made by means of electroplating.

18. The method for making an LED heat-radiating substrate as claimed in claim 13, wherein said layer bodies are made by means of casting.

19. The method for making an LED heat-radiating substrate as claimed in claim 13, wherein said layer bodies are made by means of electroforming.

20. The method for making an LED heat-radiating substrate as claimed in claim 13, wherein said low expansion layer body is a tungsten layer body or a molybdenum layer body.

21. The method for making an LED heat-radiating substrate as claimed in claim 20, wherein said layer bodies are slabs.

22. The method for making an LED heat-radiating substrate as claimed in claim 13, wherein said high thermal conductivity layer bodies are copper layer bodies.

23. The method for making an LED heat-radiating substrate as claimed in claim 22, wherein said layer bodies are slabs.

24. A method for making an LED heat-radiating substrate comprising the steps of:
providing high thermal conductivity powder bodies and low expansion powder bodies;
mixing said high thermal conductivity powder bodies and said low expansion powder bodies;
pressing the mixed high thermal conductivity powder bodies and low expansion powder bodies to form a solid body; and
sintering the pressed solid body to form a heat-radiating substrate with high thermal conductivity and low expansion.

25. The method for making an LED heat-radiating substrate as claimed in claim 24, wherein said low expansion powder bodies are tungsten powder bodies, molybdenum powder bodies, diamond powder bodies or silicon carbide powder bodies.

26. The method for making an LED heat-radiating substrate as claimed in claim 24, wherein said high thermal conductivity powder bodies are copper powder bodies.

27. A method for making an LED heat-radiating substrate, the method comprising the steps of:
providing low expansion powder bodies;
pressing said low expansion powder bodies to form a solid body;
sintering the pressed solid body to form a sintered body having holes;
permeating high thermal conductivity liquid into said holes of the sintered body; and
solidifying said high thermal conductivity liquid in the sintered body to form a heat-radiating substrate with high thermal conductivity and low expansion.

28. The method for making an LED heat-radiating substrate as claimed in claim 27, wherein said low expansion powder bodies are tungsten powder bodies, molybdenum powder bodies, diamond powder bodies or silicon carbide powder bodies.

29. The method for making an LED heat-radiating substrate as claimed in claim 24, wherein said high thermal conductivity liquid is liquid copper.
